(19) United States
(12) Patent Application Publication
(10) Pub. No.: US 2020/0303586 A1
(43) Pub. Date: Sep. 24, 2020

(54) MICRO-LED STRUCTURES WITH IMPROVED INTERNAL QUANTUM EFFICIENCY

(71) Applicant: Intel Corporation, Santa Clara, CA (US)

(72) Inventor: Khaled Ahmed, San Jose, CA (US)

(73) Assignee: Intel Corporation, Santa Clara, CA (US)

(21) Appl. No.: 16/946,224

(22) Filed: Jun. 10, 2020

(51) Int. Cl. H01L 33/06; H01L 25/075; H01L 27/12; H01L 33/22; H01L 33/32; H01L 33/00

(52) U.S. Cl. CPC H01L 33/06; H01L 25/0753; H01L 27/1214; H01L 33/0093; H01L 33/32; H01L 33/007; H01L 33/22

(57) ABSTRACT

A micro-light emitting diode (LED) pixel element and a method of fabricating the same. The pixel element includes a mask layer and a N-type core partially in an opening of the mask layer; a quantum well structure on the N-type core including at least one quantum well, each quantum well including an active layer, and at least two barrier layers including a first barrier layer and a second barrier layer, and a P-cladding layer on the quantum well structure. The active layer includes at least one of AlInN, InGaN, InGaNY or InGaNSc. The at least two barrier layers include: GaScN, wherein the active layer is in contact with and between the first barrier layer and the second barrier layer; or a GaN-based material, wherein the first barrier layer includes GaN, and is in contact with a surface of the active layer facing away from the N-type core, and the second barrier layer is a cap layer that includes at least one of AlGaN or ScGaN, and is in contact with a surface of the first barrier layer facing away from the N-type core. The cap layer is grown using pulse metalorganic chemical vapor deposition at a temperature below 600 degrees Celsius.

### TECHNICAL FIELD

Embodiments relate to micro-light-emitting-diode (LED) structures and micro-LED displays and, in particular, to the fabrication of micro-LED structures.

BACKGROUND

Displays having micro-scale light-emitting diodes (LEDs) are known as micro- LED, mLED, and pLED. As the name implies, micro-LED displays have arrays of micro- LEDs forming the individual pixel elements of a display. Micro-LED displays promise a 3× to 5× reduced power consumption as compared to organic LED (OLED) displays. OLED displays are made of small LEDs made of organic materials.

Monolithic manufacturing of high efficiency green and blue micro-LEDs has been demonstrated using nanowire LED technology based on the gallium nitride (GaN) material system. However, it has been challenging to obtain high efficiency red micro-LEDs using the GaN material system, especially when using larger scale silicon wafers of about 300 mm

### BRIEF DESCRIPTION OF THE DRAWINGS

FIG. 1 is a schematic illustration of a micro-LED display architecture, in accordance with an embodiment of the present disclosure.

FIGS. 2A-2C are cross-sections showing three different options for micro-LED pixel structures according to the prior art.

FIG. 3A is a cross section showing another prior art nanopyramid structure

FIGS. 3B and 3C show a micro-LED nanopyramid structures according to two separate embodiments.

FIG. 4A is a plot of maximum IQE as a function of emission wavelength for a historical survey of experimental data of “planar” InGaN/GaN LED devices over the UV-to-Visible range.

FIGS. 4B and 4C are respective schematics of band diagrams of GaN/InGaN/GaN quantum wells with different growth planes.

FIG. 5 is a block diagram of an exemplary computing device in which technologies described herein may be implemented.

FIG. 6 is a block diagram of an exemplary processor core that can execute instructions as part of implementing technologies described herein.

FIG. 7 is an exemplary arrangement of micro-LED elements according to some embodiments; and

FIG. 8 is a flow diagram showing a process according to some embodiments.

### DETAILED DESCRIPTION

Embodiments pertain to micro light-emitting diode (LED) displays and to the fabrication of the same, and to a device and method for making full-color micro-LEDs.

In the following description, specific details are set forth, but embodiments of the technologies described herein may be practiced without these specific details. Well-known circuits, structures, and techniques have not been shown in detail to avoid obscuring an understanding of this description. “An embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or in any other manner “Connected” may indicate elements are in direct physical or electrical contact with each other and “coupled” may indicate elements co-operate or interact with each other, but they may or may not be in direct physical or electrical contact. Terms modified by the word “substantially” include arrangements, orientations, spacings or positions that vary slightly from the meaning of the unmodified term. For example, a microphone located substantially at the center of a display includes microphones located within a few pixels of the center of the display.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

The description may use the phrases “in an embodiment,” “in embodiments,” “in some embodiments,” and “in various embodiments,” each of which may refer to one or more of the same or different embodiments. Furthermore, the terms “comprising,” “including,” “having,” and the like, as used with respect to embodiments of the present disclosure, are synonymous.

Displays based on inorganic micro-LEDs have attracted increasing attention for applications in emerging portable electronics and wearable computers such as head-mounted displays and wristwatches. Micro-LEDs are first manufactured on wafers made, for example, of sapphire or silicon and then transferred onto a display backplane glass substrate on which active matrix thin-film transistors have been manufactured. Micro-LEDs with inorganic LEDs have better reliability then OLEDs.

Reference is now made to the drawings, wherein similar or same numbers may be used to designate the same or similar parts in different figures. The use of similar or same numbers in different figures does not mean all figures including similar or same numbers constitute a single or same embodiment. In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims.

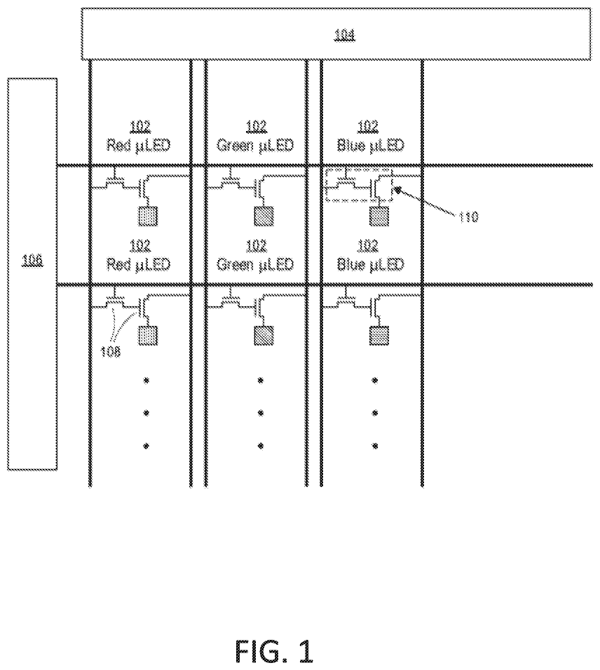

FIG. 1 is a schematic illustration of a micro-LED display architecture, in accordance with an embodiment of the present disclosure. Referring to FIG. 1, micro-LEDs 102 are arranged in a matrix. The micro-LEDs are driven through “Data Driver” 104 and “Scan Driver” 106 chips. Thin film transistors 108 are used to make “pixel driver circuits” 110 for each micro-LED. In an embodiment, the micro-LEDs are fabricated on, for example, a silicon or sapphire wafer then transferred to a glass substrate called “backplane” where the “pixel driver circuits” 110 have been fabricated using thin film transistors.

Similar to OLED, micro-LED technology is an emissive display technology. However, due to the inorganic nature of the emitting materials, their efficiency and narrow emission bands, micro-LEDs also offer the prospect of significantly improved performance in terms of energy consumption, color gamut, brightness, contrast (High Dynamic Range), long lifetime and environmental stability (e.g., no or low sensitivity to air and moisture), and/or compatibility with flexible backplane technologies to enable curved or flexible displays.

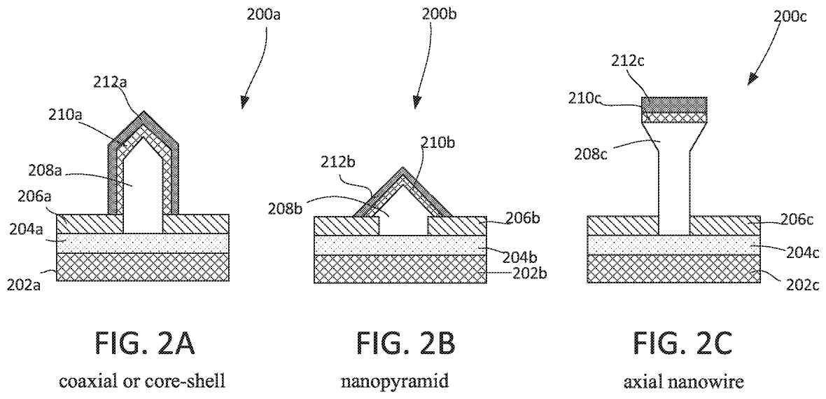

FIGS. 2A-2C are cross-sections showing three different options for micro-LED pixel structures 200a, 200b and 200c, where 200a corresponds to a coaxial or core-shell structure, 200b corresponds to a nanopyramid structure (for example a hexagonal pyramid structure), and 200c corresponds to an axial nanowire structure. Silicon (for example Si (111)) or sapphire wafers 202a/202b/202c may include thereon a nucleation layer 204a/204b/204c such as one including a stack of MN/AlN layers with MN denoting metal nitride, where the metal in M may be, for example, Ti, Hf, Nb, etc., and MN denoting aluminum nitride. A mask 206a/206b/206c defines openings therein exposing portions of the nucleation layer. The mask may be made of silicon nitride (Si₃N₄) by way of example, and can have an opening dimension of about 100-500 nm. The N-Core 208a/208b/208c and P-cladding 212a/212b/212c may be made of P—GaN, and the active layers 210a/210b/210c may be made of layers of indium gallium nitride (InGaN) and GaN that may alternate to form multiple quantum wells (MQW), according to some exemplary embodiments. The N-core's diameter may be from about 50 nm to about 300 nm. The height of the pyramid may be from about 1 μm to about 10 μm.

Options for making efficient red micro-LEDs, or micro-LEDs corresponding to colors including long wavelength colors, such as red, orange, yellow or green, are shown in Table 1 below for each type of micro-LED pixel structure shown in FIGS. 2A-2C, and for planar micro-LED pixel structures. By “long wavelength,” what is meant herein is a wavelength longer than blue and up to the visible infrared (IR) range. Table 1 pertain to InGaN as the active layer, which determines the color of emission. For red emission, the active layer of InGaN may include about 45% atomic concentration of indium, but for blue it may need to include about 20% indium, and for green about 30 to about 31% indium. Specifically, Table 1 shows a comparison of various options for making efficient red micro-LEDs with GaN materials through various maximum indium percentage content of the InGaN layer, and with respect to associated growth planes for multiple quantum well (MQW) structures. “(st)” in each cell means a “show-stopper” issue for display applications, while “(gd)” in each cell means “good.” As can be seen below, the maximum Indium content for the planar and core-shell micro-LED pixel structures tend to create show-stopper circumstances with respect to the maximum red internal quantum efficiency (IQE) of the micro-LED pixel structure. In addition, Table 1 also shows that, when scaling to 300 mm silicon wafers for micro-LED production for axial nanowire micro-LED pixel structures, fabrication of an the micro-LED with the stated parameters can be problematic. Also problematic would be the fabrication of a pyramid micro-LED pixel structure with the stated parameter as indicated by a large full-width-at-half-maximum value (FWHM) of the normalized output luminance as plotted against emission wavelength far field angle.

TABLE 1

| | | Core-Shell | Axial | |
|---|---|---|---|---|
| | | Nanowire | Nanowire | Nano- |
| Metric | Planar | (NW) | (NW) | pyramid |
| Growth | c-plane | m-plane | c-plane | r-plane |
| Plane | | | | |
| for MQW | | | | |
| Maximum | 30% (st) | 35% (st) | 45% (gd) | 45% (gd) |
| Indium | | | | |
| atomic | | | | |
| concen- | | | | |
| tration | | | | |
| Growth | MOCVD (gd) | MOCVD (gd) | MBE | MOCVD (gd) |
| Tech- | | | | |
| nology | | | | |
| Maximum | 4% (st) | 4% (st) | 16% (gd) | 16% (gd) |
| Red IQE | | | | |
| Main | Low IQE (st) | Low IQE (st) | Scaling to | Large |
| Issue | | | 300 mm | FWHM (st) |
| | | | (st) | |

Referring still to Table 1, the planar structure does not allow for the formation of InGaN active layers with an atomic concentration of indium higher than 32%, and thus efficient red emission is not possible. Core-shell nanowire has relatively lower Indium incorporation on the m-plane, making it difficult to reach >40% Indium composition required for red emission. Axial nanowire allows for high Indium incorporation and relatively higher efficiency for red micro-LED. However, with for an axial nanowire micro-LED pixel structure, molecular beam epitaxy (MBE) is required for the growth, but MBE is not scalable to 300 mm size wafers and is difficult to manufacture in general, which can negatively affect the speed and also economics of making micro-LED displays. Finally, the nanopyramid structure can allow for high indium incorporation on the r-planes. However, the indium composition along the pyramid facets is nonuniform, causing 2× wider emission spectrum, negatively affecting the color purity and color gamut of the display, hence the large FWHM value. A higher indium content for active layer typically results in a poorer material in terms of quantum efficiency. Blue emission does not pose as much of a problem because blue requires a lower In content in the active layer of a micro-LED pixel structure. For long wavelengths (i.e. wavelengths longer than those associated with blue emissions but shorter than those associated with IR emissions in the visible range), there are problems with respect to quantum efficiency, because more In content is needed for such emissions. Embodiments provide some solutions to produce higher efficiency long wavelength micro-LEDs, such as for red and green emissions and any color in between

Some embodiments including apparatuses and methods are proposed to provide high efficiency emission, such as warm color emission, for example red emission, using GaN-based material system.

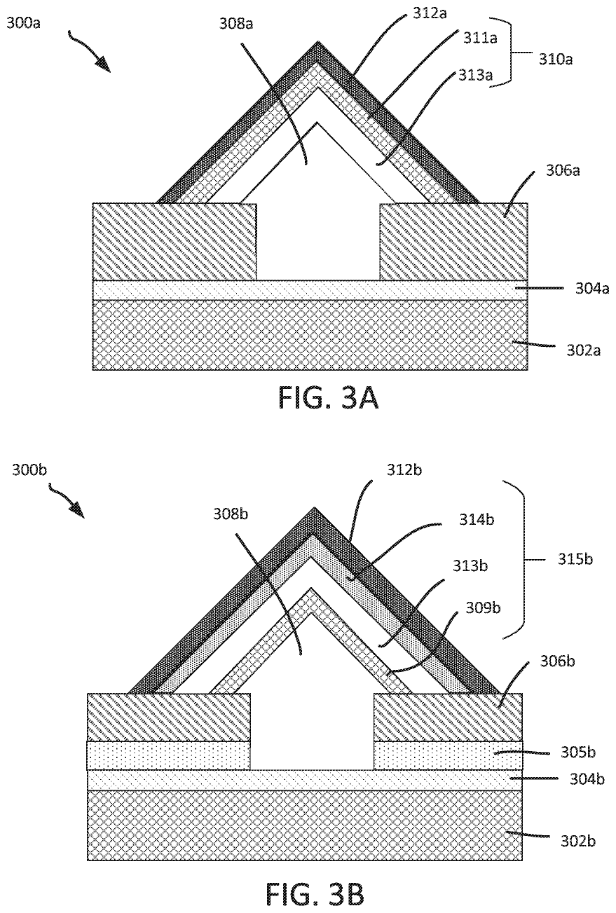

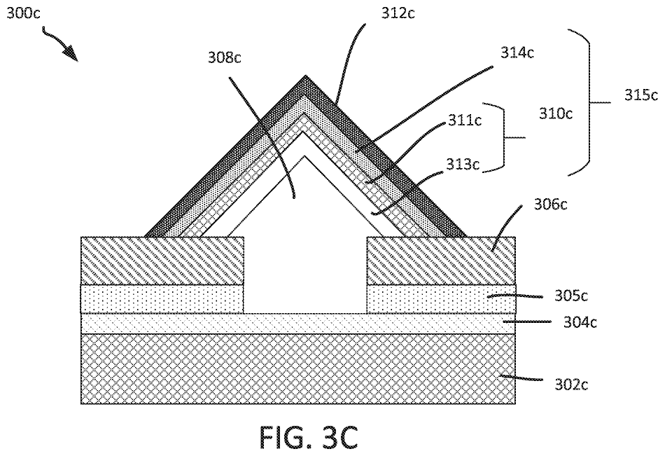

Reference is now made to FIGS. 3A, 3B and 3C, where 3A shows a prior art nanopyramid structure 300a, and FIGS. 3B and 3C show a nanopyramid structures 300b and 300c according to two separate embodiments. With respect to both FIGS. 3A, 3B and 3C, following the fabrication of the ordered N-type GaN nanopyramids 308a/308b/308c cores grown out of the silicon wafer 302a/302b/302c, for example using selective epitaxy, the rest of the LED structure is grown on the nanopyramid core.

Referring to FIG. 3A, the structure 300a of the same may be similar to that shown in FIG. 2A, except for further detail provided with respect to the active layers. The quantum well 310a is shown as including a layer of InGaN 313a grown onto the N-type GaN core 308a, and barrier layer of GaN 311a on the InGaN layer 313a. Silicon (for example Si (111)) or sapphire wafers 302a may include thereon a nucleation layer 304a such as one including AlN having a thickness of about 25 nm. A mask 306a defines openings therein exposing portions of the nucleation layer. The mask may be made of silicon nitride (Si₃N₄) by way of example, and can have an opening dimension of about 100-500 nm, and a thickness of about 80 nm. The N-Core 308a and P-cladding 312a may be made of P—GaN, and the active layers 310a may be made of layers of indium gallium nitride (InGaN) and GaN that may alternate to form multiple quantum wells (MQW), according to some exemplary embodiments. Each layer of InGaN may have a thickness of about 3 nm, and each barrier layer of GaN may have a thickness of about 10 nm. The cladding layer 312a may have a thickness of about 60 nm. The N-core's diameter may be from about 50 nm to about 300 nm. The height of the pyramid may be from about 600 nm to 1000 nm.

Referring to FIG. 3B, the structure 300b includes a quantum well 310b shown as including a first barrier layer 309b, which may include Ga_{0.5}Sc_{0.5}N, grown onto the N-type GaN core 308a, an active layer 313b grown onto the first barrier layer 309b, the active layer including, for example, at least one of AlInN, InGaN, InGaNY, or InGaNSc, followed by a second barrier layer 314b which may include Ga_{0.5}Sc_{0.5}N. A quantum well structure for the micro-LED pixel structure of the embodiment of FIG. 3C may, according to some embodiments, include one or more repetitions of quantum well 310b with successive layers of the first barrier layer, active layer and second barrier layer with any of the materials for each layer as described by way of example above in order to form a multiple quantum well (MQW) micro-LED pixel structure. In the shown embodiment of FIG. 3B, the first barrier layer 309b may have a thickness of about 10 nm, or of about 5 nm to about 15 nm, the active layer 313b may have a thickness of about 3 nm, or of about 2 nm, to about 5 nm, and the second barrier layer may have a thickness of about 10 nm, or of about 5 nm to about 15 nm. Silicon (for example Si (111)) or sapphire wafers 302b may include thereon a nucleation layer 304b such as one including AlN having a thickness of about 25 nm to about 50 nm. A mask 306a defines openings therein exposing portions of the nucleation layer 304b. The mask may be made of silicon nitride (Si₃N₄) by way of example, and can have an opening dimension of about 50 nm to about 200 nm and even up to 500 nm, and a thickness of about 80 nm, or of about 50 nm to about 200 nm. The N-Core 308b and P-cladding 312b may be made of GaN where, for the N-core, the GaN is n-doped, and for the P-cladding, the GaN is p-doped. The P-cladding layer 312b may further be made of p-doped Ga_{0.5}Sc_{0.5}N, and have a thickness of about 60 nm, or of about 50 nm to about 100 nm. The N-core's diameter may be from about 50 nm to about 300 nm. The height of the pyramid may be from about 600 nm to 1000 nm. The structure 300b further includes a release layer 305b as shown disposed between the nucleation layer 304b and the mask layer 306b. The release layer may include TiN, and may have a thickness of about 10 nm, or of about 10 nm to about 30 nm. A function of the release layer 305b is to allow the micro-LED nanopyramid, including quantum well(s) and its mask layer 306b, to be released to the backplane of a display during transfer of the same, where applying IR through the wafer 302b would ablate the release layer to create pressure to release the nanopyramid from the nucleation layer 304b.

Referring to FIG. 3C, the structure 300c includes a quantum well 310c shown as including an active layer 313c grown onto the N-type GaN core 308a, the active layer including, for example, at least one of AlInN, InGaN, InGaNY, or InGaNSc, followed by a first barrier layer 311c, which may include GaN, and a second barrier layer or cap layer 314c which may in turn include AlGaN or ScGaN. A quantum well structure for the micro-LED pixel structure of the embodiment of FIG. 3C may, according to some embodiments, include one or more repetitions of quantum well 310c with successive layers of the active layer, first barrier layer, and second barrier layer with any of the materials for each layer as described by way of example above in order to form a multiple quantum well (MQW) micro-LED pixel structure. The cap layer 314b may, for example have a crystalline aluminum or scandium atomic concentration of about 30% to about 50%, using, for example, a low temperature “Flow Modulation Epitaxy” or “Pulsed MOCVD” (pulsed metalorganic chemical vapor deposition) on top of a high indium content layer 313c of quantum well 310c. Using pulse MOCVD yields a better quality of material at lower growth temperatures so as not to affect the underlying layers including the active layers with higher growth temperatures.

In the shown embodiment of FIG. 3C, the active layer 313c may have a thickness of about 3 nm, or of about 2 nm to about 5 nm, the first barrier layer 311c may have a thickness of about 10 nm, or of about 5 nm to about 15 nm, and the second barrier layer may have a thickness of about 3 nm, or of about 2 nm to about 10 nm. Silicon (for example Si (111)) or sapphire wafers 302c may include thereon a nucleation layer 304c such as one including MN having a thickness of about 25 nm to about 50 nm. A mask 306a defines openings therein exposing portions of the nucleation layer 304c. The mask may be made of silicon nitride (Si₃N₄) by way of example, and can have an opening dimension of about 50 nm to about 200 nm and even up to 500 nm, and a thickness of about 80 nm, or of about 50 nm to about 200 nm. The N-Core 308c and P-cladding 312c may be made of P—GaN. The P-cladding layer 312c may further have a thickness of about 60 nm, or of about 50 nm to about 100 nm. The N-core's diameter may be from about 50 nm to about 300 nm. The height of the pyramid may be from about 1 μm to about 10 μm. The structure 300c further includes a release layer 305c as shown disposed between the nucleation layer 304c and the mask layer 306c. The release layer may include TiN, and may have a thickness of about 10 nm, or of about 10 nm to about 30 nm. A function of the release layer 305c is to allow the micro-LED nanopyramid, including quantum well(s) and its mask layer 306c, to be released to the backplane of a display during transfer of the same, where applying IR through the wafer 302c would ablate the release layer to create pressure to release the nanopyramid from the nucleation layer 304c.

According to one embodiment, where the active layer 313c includes InGaN, the active layer 313c may include the growth of an undoped shell layer comprising an underlayer of InₓGa₁₋ₓN in contact with the N-type GaN core nanopyramid 308c, with x≈0-0.05, and a subsequent layer on top of the underlayer made of In_{y}Ga_{1-y}N with y≈0.4-0.45. The In_{y}Ga_{1-y}N layer may be grown by low temperature, pulsed MOCVD that is being developed. This process may use NH₃ or N₂H₄ as a nitrogen source. Where the cap layer 314c includes AlGaN, it may include an Al_{z}Ga_{1-z}N layer with a z≈0.3-0.4. The cap layer may have a thickness of between about 2 nm to about 10 nm as noted above, or between about 1 nm to about 1.5 nm. The InₓGa₁₋ₓN layer may have a thickness of about 8-12 nm, and the In_{y}Ga_{1-y}N layers have thickness of about 3nm to about 4nm.

The structure of FIG. 3C yields a high integrity of the In containing active layers in nanopyramid LEDs (i.e. no phase separation) especially with an In atomic concentration higher than 30%, such as for the emission of long wavelength light. The cap layer 314c helps keep the high indium in the active layer, and further helps compensate for the strain that results from growing the active layer on top of the core material 308c, or the In_{y}Ga_{1-y}N layer on top of the InₓGa₁₋ₓN layer, resulting in a much better active layer for emitting efficient light in the long wavelength range. The high bandgap cap layer, for example in the MQW structure, helps enhance quantum confinement and thus improve light conversion efficiency when electrons and holes wavefunctions overlap in the active emission layer.

The embodiments of FIGS. 3B and 3C propose structures that are designed to facilitate the manufacturing of micro-LEDs on 300 mm silicon wafers, enabling faster manufacturing of micro-LED elements that have high color purity and low power consumption, and that are further affordable. Some embodiments further provide high power efficacy of the resulting nanopyramid micro LED elements even for red and green colors. The high power efficacy results in lower display power consumption, which is the main value proposition of micro-LED displays compared to OLED displays.

Embodiments, such as shown by way of example in in FIGS. 3B and 3C, lead to the generation of micro-LED elements (including the mask layer 306b/306c, the N-type core 308b/308c, the quantum well structure including barrier layers and the active layer of each quantum well of the quantum well structure, and the P-cladding) that are to be transferred onto the backplane of a display, such as a glass backplane of a display in a manner within the knowledge of a skilled person.

It is noted that embodiments herein are not limited to nanopyramid micro-LED pixel structures, but are applicable to any micro-LED pixel structures that use In in they active layers in order to generate long wavelength emissions.

To provide context, an issue with efficiency of GaN-based red micro LEDs for light emitting devices, such as light emitting diodes (LED), is that the emission wavelength is determined by the band gap of the active region of the LED together with thickness determined confinement effects. Often, the active region includes one or more quantum wells (QWs). For III-nitride based LED devices, such as GaN based devices, the active region (e.g., quantum well) material is preferably ternary, such as InₓGa₁₋ₓN, where The band gap of such III-nitride can be dependent on the amount of In incorporated in the active region (e.g., in the QW(s)). A higher In incorporation can yield a smaller band gap and thus longer wavelength of the emitted light. InGaN may be a very attractive material for the development of various optical devices in the entire visible spectral range owing to the tenability of the bandgap energy by adjusting the indium content. A low-In-content InGaN-based blue light-emitting diode (LED) has exhibited an external quantum efficiency (EQE) of about 83%. However, the EQEs of long-wavelength LEDs emitting light in the green, yellow, orange, and red regions can be much lower.

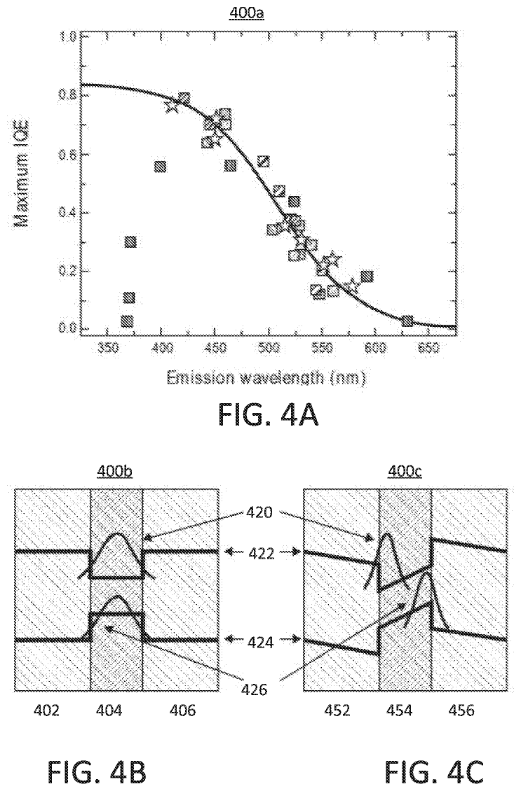

As an example of the above, FIG. 4A is a plot 400a of maximum IQE as a function of emission wavelength for a historical survey of experimental data of “planar” InGaN/GaN micro-LED devices over the UV-to-Visible range. Referring to plot 400a, the maximum internal quantum efficiency (IQE) decreases as a function of wavelength.

To provide further context, critical factors causing low efficiency in high-In-content InGaN-based micro-LEDs may include (1) defects in the InGaN active layer due to the lattice mismatch between InₓGaₓ₋₁N and GaN (e.g., lattice mismatch between InN and GaN is 11%), and/or (2) the piezoelectric field in the strained InGaN active layers can become very large for high indium content, causing low internal quantum efficiency owing to electron-hole separation in InGaN multiple quantum wells. This can be particularly important for growing InGaN on c-plane GaN. For a/m-planes, however, the effect may be negligible.

As an example of the above, FIGS. 4B and 4C are schematic of band diagrams of GaN/InGaN/GaN quantum wells with different growth planes, in accordance with an embodiment of the present disclosure. Referring to FIG. 4A, an a/m-plane structure 400b is shown for GaN 402, InGaN 404 and GaN 406 layers. A c-plane structure 400c is shown for GaN 452, InGaN 454 and GaN 456 layers. Corresponding parameters shown for the differing structures include electron wave function 420, conduction band edge 422, valence band edge 424 and hole wave function 426.

Low temperature cap layer growth is a main aspect of enabling some demonstrative embodiments. Low temperature AlGaN cap layers were grown using pulsed MOCVD (or Flow Modulation Epitaxy (FME)) with NH₃ as N-precursor at various growth temperatures including about 500 degrees Celsius and about 550 degrees Celsius. Secondary ion mass spectrometry (SIMS) results of GaN film growth showed a significant reduction in residual oxygen and carbon impurity incorporation in the FME films.

In accordance with one or more embodiments of the present disclosure, a method of manufacturing a micro-light emitting diode (LED) pixel structure comprises: providing a wafer including a nucleation layer thereon; providing a micro-LED pixel element on the nucleation layer including: growing a mask layer on the nucleation layer, the mask layer defining an opening therein; growing a N-type core on the nucleation layer; and in the opening of the mask layer; growing a quantum well structure on the N-type core, the quantum well structure including at least one quantum well, each quantum well of the at least one quantum well including an active layer, and at least two barrier layers including a first barrier layer and a second barrier layer, and growing a P-cladding layer on the quantum well structure, the P-cladding layer including a P-type semiconductor material. The active layer includes at least one of AlInN, InGaN, InGaNY or InGaNSc; and the at least two barrier layers according to a first option include GaScN, wherein the first barrier layer is in contact with a surface of the active layer facing the N-type core, and the second barrier layer is in contact with a surface of the active layer facing away from the N-type core. According to a second option, the at least two barrier layers include a GaN-based material, wherein the first barrier layer includes GaN, and is in contact with a surface of the active layer facing away from the N-type core, and the second barrier layer is a cap layer that includes at least one of AlGaN or ScGaN, and is in contact with a surface of the first barrier layer facing away from the N-type core.

According to some embodiments, a source micro-LED wafer (such as a silicon wafer) has micro-LED pixel structures monolithically grown thereon. The silicon wafer may be coated with a metal-based nucleation layer (MNL). The MNL may be crystalline or polycrystalline. A silicon nitride mask may then be deposited on the MNL. Lithography may then be used to open apertures in the silicon nitride mask with diameters carefully chosen to accommodate the subsequent formation of LEDs that emit red, green, and blue colors. N-type GaN nanopyramid cores may then be grown, e.g., by metal organic chemical vapor deposition (MOCVD), as seeded from the MNL. The nanopyramid cores may have diameters in the range 50 nm to 250 nm.

In some embodiments, after fabrication of further LED layers, example of which are described above, for example in relation to FIGS. 3B and 3C, the starting source micro-LED wafer (such as a silicon wafer) is removed to allow the micro-LED pixel structure including its mask layer to be transferred onto the backplane of the display device.

An In-based active layer may be grown around the GaN core, e.g., using MOCVD. The amount of indium in the active layer may depends on the GaN core diameter.

In an embodiment, smaller core diameters result in the growth of active layers with smaller indium content. Larger core diameters result in the growth of active layers with larger indium content. For blue (B) color emission, the indium atomic concentration may be about 20%. For green (G) color emission, the indium atomic concentration may be about 30%. For red (R) color emission, the indium atomic concentration may be about 40% to 45%. A p-type GaN cladding layer may be formed around the active layer, e.g., using MOCVD. The nanopyramids may be covered by an insulating material layer, e.g., a silicon oxide (SiOx) layer. A lithography and etch may then be used to expose the p-GaN cladding layer for all color nanopyramid structures. Atomic layer deposition may then be used to conformally deposit a metal layer on the p-GaN cladding layers. A metal fill process may then be performed to fill in contact metals for the micro-LED pixel structures.

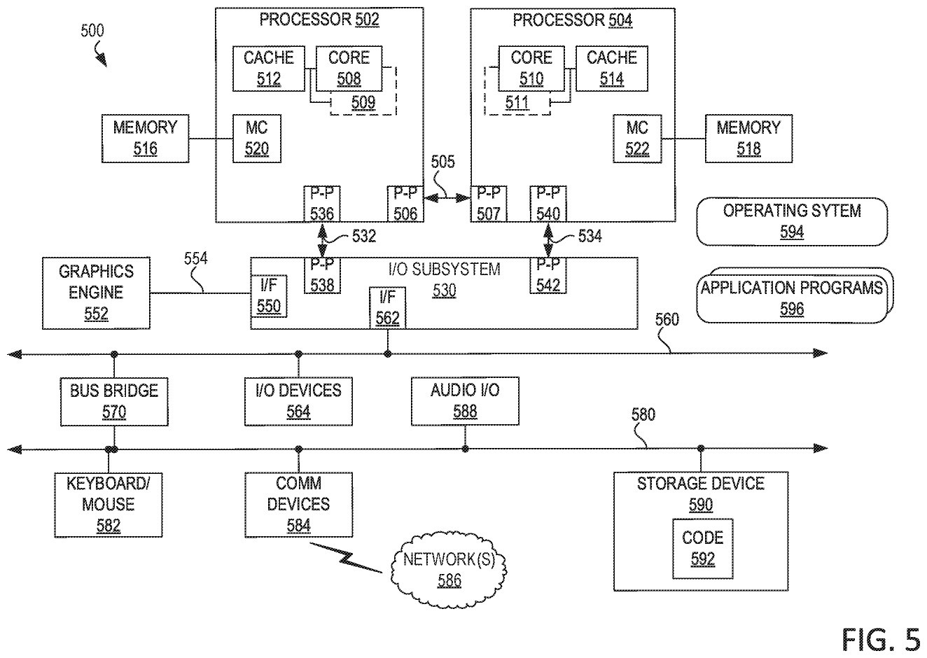

FIG. 5 is a block diagram of an exemplary computing device in which technologies described herein may be implemented. Generally, components shown in FIG. 5 can communicate with other shown components, although not all connections are shown, for ease of illustration. The device 500 is a multiprocessor system comprising a first processor 502 and a second processor 504 and is illustrated as comprising point-to-point (P-P) interconnects. For example, a point-to-point (P-P) interface 506 of the processor 502 is coupled to a point-to-point interface 507 of the processor 504 via a point-to-point interconnection 505. It is to be understood that any or all of the point-to-point interconnects illustrated in FIG. 5 can be alternatively implemented as a multi-drop bus, and that any or all buses illustrated in FIG. 5 could be replaced by point-to-point interconnects.

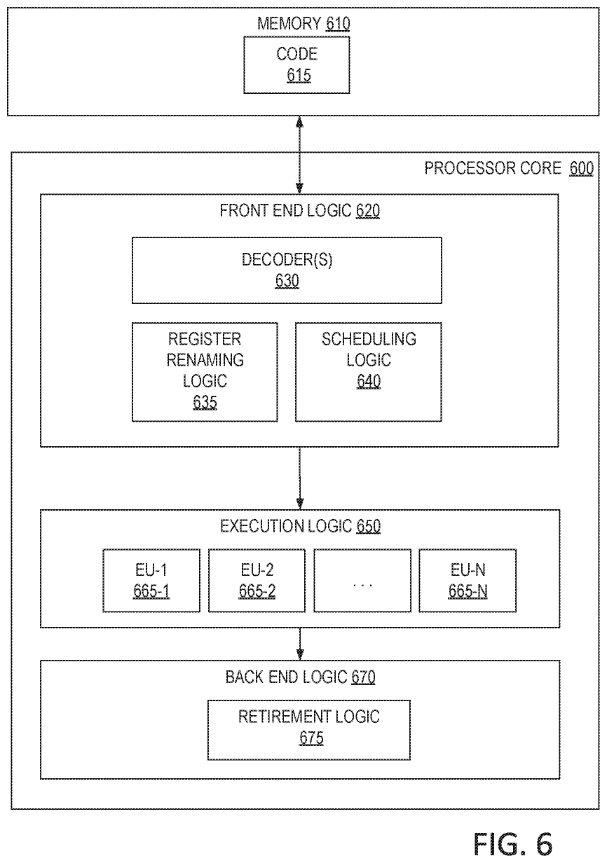

As shown in FIG. 5, the processors 502 and 504 are multicore processors. Processor 502 comprises processor cores 508 and 509,and processor 504 comprises processor cores 510 and 511. Processor cores 508-511 can execute computer-executable instructions in a manner similar to that discussed below in connection with FIG. 6, or in other manners.

Processors 502 and 504 further comprise at least one shared cache memory 512 and 514, respectively. The shared caches 512 and 514 can store data (e.g., instructions) utilized by one or more components of the processor, such as the processor cores 508-509 and 510-511. The shared caches 512 and 514 can be part of a memory hierarchy for the device 500. For example, the shared cache 512 can locally store data that is also stored in a memory 516 to allow for faster access to the data by components of the processor 502. In some embodiments, the shared caches 512 and 514 can comprise multiple cache layers, such as level 1 (L1), level 2 (L2), level 3 (L3), level 4 (L4), and/or other caches or cache layers, such as a last level cache (LLC).

Although the device 500 is shown with two processors, the device 500 can comprise any number of processors. Further, a processor can comprise any number of processor cores. A processor can take various forms such as a central processing unit, a controller, a graphics processor, an accelerator (such as a graphics accelerator or digital signal processor (DSP)) or a field programmable gate array (FPGA). A processor in a device can be the same as or different from other processors in the device. In some embodiments, the device 500 can comprise one or more processors that are heterogeneous or asymmetric to a first processor, accelerator, FPGA, or any other processor. There can be a variety of differences between the processing elements in a system in terms of a spectrum of metrics of merit including architectural, microarchitectural, thermal, power consumption characteristics and the like. These differences can effectively manifest themselves as asymmetry and heterogeneity amongst the processors in a system. In some embodiments, the processors 502 and 504 reside in the same die package.

Processors 502 and 504 further comprise memory controller logic (MC) 520 and 522. As shown in FIG. 5, MCs 520 and 522 control memories 516 and 518 coupled to the processors 502 and 504, respectively. The memories 516 and 518 can comprise various types of memories, such as volatile memory (e.g., dynamic random access memories (DRAM), static random access memory (SRAM)) or non-volatile memory (e.g., flash memory). While MCs 520 and 522 are illustrated as being integrated into the processors 502 and 504, in alternative embodiments, the MCs can be logic external to a processor and can comprise one or more layers of a memory hierarchy.

Processors 502 and 504 are coupled to an Input/Output (I/O) subsystem 530 via P- P interconnections 532 and 534. The point-to-point interconnection 532 connects a point-to-point interface 536 of the processor 502 with a point-to-point interface 538 of the I/O subsystem 530, and the point-to-point interconnection 534 connects a point-to-point interface 540 of the processor 504 with a point-to-point interface 542 of the I/O subsystem 530. Input/Output subsystem 530 further includes an interface 550 to couple I/O subsystem 530 to a graphics engine 552, which can be a high-performance graphics engine. The I/O subsystem 530 and the graphics engine 552 are coupled via a bus 554. Alternately, the bus 554 could be a point-to-point interconnection.

Input/Output subsystem 530 is further coupled to a first bus 560 via an interface 562. The first bus 560 can be a Peripheral Component Interconnect (PCI) bus, a PCI Express bus, another third generation I/O interconnection bus or any other type of bus.

Various I/O devices 564 can be coupled to the first bus 560. A bus bridge 570 can couple the first bus 560 to a second bus 580. In some embodiments, the second bus 580 can be a low pin count (LPC) bus. Various devices can be coupled to the second bus 580 including, for example, a keyboard/mouse 582, audio I/O devices 588 and a storage device 590, such as a hard disk drive, solid-state drive or other storage devices for storing computer-executable instructions (code) 592. The code 592 can comprise computer-executable instructions for performing technologies described herein. Additional components that can be coupled to the second bus 580 include communication device(s) 584, which can provide for communication between the device 500 and one or more wired or wireless networks 586 (e.g. Wi-Fi, cellular or satellite networks) via one or more wired or wireless communication links (e.g., wire, cable, Ethernet connection, radio-frequency (RF) channel, infrared channel, Wi-Fi channel) using one or more communication standards (e.g., IEEE 802.11 standard and its supplements).

The device 500 can comprise removable memory such as flash memory cards (e.g., SD (Secure Digital) cards), memory sticks, Subscriber Identity Module (SIM) cards). The memory in device 500 (including caches 512 and 514, memories 516 and 518 and storage device 590) can store data and/or computer-executable instructions for executing an operating system 594 and application programs 596. Example data includes web pages, text messages, images, sound files, video data, biometric thresholds for particular users or other data sets to be sent to and/or received from one or more network servers or other devices by the device 500 via one or more wired or wireless networks, or for use by the device 500. The device 500 can also have access to external memory (not shown) such as external hard drives or cloud-based storage.

The operating system 594 can control the allocation and usage of the components illustrated in FIG. 5 and support one or more application programs 596. The application programs 596 can include common mobile computing device applications (e.g., email applications, calendars, contact managers, web browsers, messaging applications) as well as other computing applications and utilities, such as a virtual keyboard.

The device 500 can support various input devices, such as a touchscreen, microphones, camera, physical keyboard, virtual keyboard, proximity sensor and trackball, and one or more output devices, such as a speaker and a display. Other possible input and output devices include piezoelectric and other haptic I/O devices. Any of the input or output devices can be internal to, external to or removably attachable with the device 500. External input and output devices can communicate with the device 500 via wired or wireless connections.

In addition, the computing device 500 can provide one or more natural user interfaces (NUIs). For example, the operating system 594 or applications 596 can comprise speech recognition logic as part of a voice user interface that allows a user to operate the device 500 via voice commands Further, the device 500 can comprise input devices and logic that allows a user to interact with the device 500 via a body, hand or face gestures. For example, a user's hand gestures can be detected and interpreted to provide input to a gaming application.

The device 500 can further comprise one or more communication components 584. The components 584 can comprise wireless communication components coupled to one or more antennas to support communication between the system 500 and external devices. The wireless communication components can support various wireless communication protocols and technologies such as Near Field Communication (NFC), Wi-Fi, Bluetooth, 4G Long Term Evolution (LTE), Code Division Multiplexing Access (CDMA), Universal Mobile Telecommunication System (UMTS) and Global System for Mobile Telecommunication (GSM). In addition, the wireless modems can support communication with one or more cellular networks for data and voice communications within a single cellular network, between cellular networks, or between the mobile computing device and a public switched telephone network (PSTN).

The device 500 can further include at least one input/output port (which can be, for example, a USB, IEEE 1394 (FireWire), Ethernet and/or RS-232 port) comprising physical connectors; a power supply; a satellite navigation system receiver, such as a GPS receiver; a gyroscope; an accelerometer; a proximity sensor; and a compass. A GPS receiver can be coupled to a GPS antenna. The device 500 can further include one or more additional antennas coupled to one or more additional receivers, transmitters and/or transceivers to enable additional functions.

It is to be understood that FIG. 5 illustrates only one exemplary computing device architecture. Computing devices based on alternative architectures can be used to implement technologies described herein. For example, instead of the processors 502 and 504, and the graphics engine 552 being located on discrete integrated circuits, a computing device can comprise an SoC (system-on-a-chip) integrated circuit incorporating multiple processors, a graphics engine and additional components. Further, a computing device can connect elements via bus or point-to-point configurations different from that shown in FIG. 5. Moreover, the illustrated components in FIG. 5 are not required or all-inclusive, as shown components can be removed and other components added in alternative embodiments.

FIG. 6 is a block diagram of an exemplary processor core 600 to execute computer-executable instructions as part of implementing technologies described herein. The processor core 600 can be a core for any type of processor, such as a microprocessor, an embedded processor, a digital signal processor (DSP) or a network processor. The processor core 600 can be a single-threaded core or a multithreaded core in that it may include more than one hardware thread context (or “logical processor”) per core.

FIG. 6 also illustrates a memory 610 coupled to the processor 600. The memory 610 can be any memory described herein or any other memory known to those of skill in the art. The memory 610 can store computer-executable instruction 615 (code) executable by the processor core 600.

The processor core comprises front-end logic 620 that receives instructions from the memory 610. An instruction can be processed by one or more decoders 630. The decoder 630 can generate as its output a micro operation such as a fixed width micro operation in a predefined format, or generate other instructions, microinstructions, or control signals, which reflect the original code instruction. The front-end logic 620 further comprises register renaming logic 635 and scheduling logic 640, which generally allocate resources and queues operations corresponding to converting an instruction for execution.

The processor core 600 further comprises execution logic 650, which comprises one or more execution units (EUs) 665-1 through 665-N. Some processor core embodiments can include a number of execution units dedicated to specific functions or sets of functions. Other embodiments can include only one execution unit or one execution unit that can perform a particular function. The execution logic 650 performs the operations specified by code instructions. After completion of execution of the operations specified by the code instructions, back-end logic 670 retires instructions using retirement logic 675. In some embodiments, the processor core 600 allows out of order execution but requires in-order retirement of instructions. Retirement logic 670 can take a variety of forms as known to those of skill in the art (e.g., re-order buffers or the like).

The processor core 600 is transformed during execution of instructions, at least in terms of the output generated by the decoder 630, hardware registers and tables utilized by the register renaming logic 635, and any registers (not shown) modified by the execution logic 650. Although not illustrated in FIG. 6, a processor can include other elements on an integrated chip with the processor core 600. For example, a processor may include additional elements such as memory control logic, one or more graphics engines, I/O control logic and/or one or more caches.

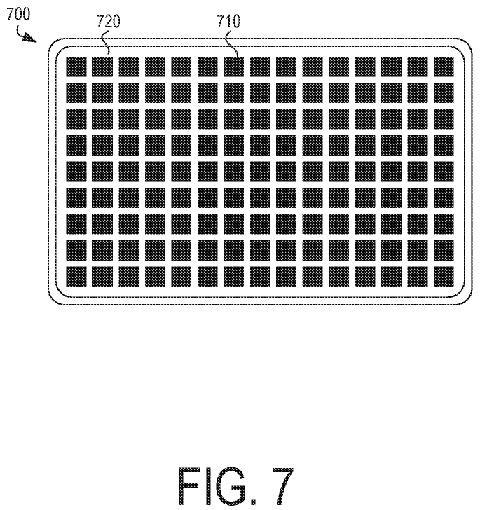

FIG. 7 illustrates exemplary arrangements of micro-LED elements according to some embodiments and arranged in a display 700, which may correspond to the display architecture of FIG. 1. On display 700, an array of micro-LED elements 710, such as those described in relation of any of the embodiments above, are distributed across a display area 720 which corresponds to a backplane of the display. The display may be a glass display, such as, by way of example a touchscreen display, or a non-touchscreen display.

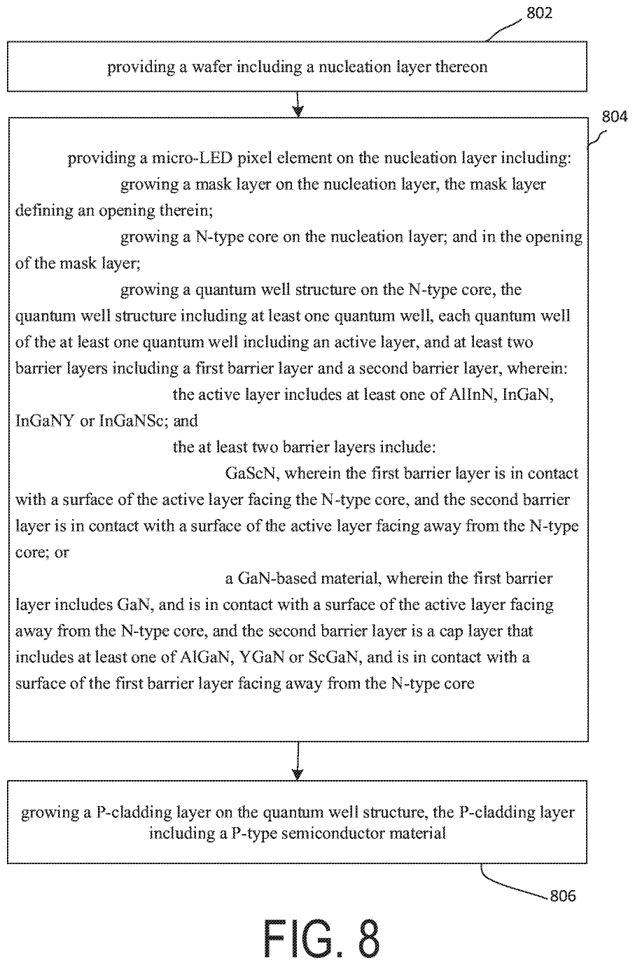

FIG. 8 shows a process 800 according to some embodiments. In process 800, at operation 802, providing a wafer including a nucleation layer thereon; at operation 804, providing a micro-LED pixel element on the nucleation layer including: growing a mask layer on the nucleation layer, the mask layer defining an opening therein; growing a N-type core on the nucleation layer; and in the opening of the mask layer; growing a quantum well structure on the N-type core, the quantum well structure including at least one quantum well, each quantum well of the at least one quantum well including an active layer, and at least two barrier layers including a first barrier layer and a second barrier layer, wherein: the active layer includes at least one of AlInN, InGaN, InGaNY or InGaNSc; and the at least two barrier layers include: GaScN, wherein the first barrier layer is in contact with a surface of the active layer facing the N-type core, and the second barrier layer is in contact with a surface of the active layer facing away from the N-type core; or a GaN-based material, wherein the first barrier layer includes GaN, and is in contact with a surface of the active layer facing away from the N-type core, and the second barrier layer is a cap layer that includes at least one of AlGaN or ScGaN, and is in contact with a surface of the first barrier layer facing away from the N-type core; and at operation 806, growing a P-cladding layer on the quantum well structure, the P-cladding layer including a P-type semiconductor material.

As used in any embodiment herein, the term “module” refers to logic that may be implemented in a hardware component or device, software or firmware running on a processor, or a combination thereof, to perform one or more operations consistent with the present disclosure. Software may be embodied as a software package, code, instructions, instruction sets and/or data recorded on non-transitory computer readable storage mediums. Firmware may be embodied as code, instructions or instruction sets and/or data that are hard-coded (e.g., nonvolatile) in memory devices. As used in any embodiment herein, the term “circuitry” can comprise, for example, singly or in any combination, hardwired circuitry, programmable circuitry such as computer processors comprising one or more individual instruction processing cores, state machine circuitry, and/or firmware that stores instructions executed by programmable circuitry. Modules described herein may, collectively or individually, be embodied as circuitry that forms a part of one or more devices. Thus, any of the modules can be implemented as circuitry, such as continuous itemset generation circuitry, entropy-based discretization circuitry, etc. A computer device referred to as being programmed to perform a method can be programmed to perform the method via software, hardware, firmware or combinations thereof.

Any of the disclosed methods can be implemented as computer-executable instructions or a computer program product. Such instructions can cause a computer or one or more processors capable of executing computer-executable instructions to perform any of the disclosed methods. Generally, as used herein, the term “computer” refers to any computing device or system described or mentioned herein, or any other computing device. Thus, the term “computer-executable instruction” refers to instructions that can be executed by any computing device described or mentioned herein, or any other computing device.

The computer-executable instructions or computer program products, as well as any data created and used during implementation of the disclosed technologies, can be stored on one or more tangible or non-transitory computer-readable storage media, such as optical media discs (e.g., DVDs, CDs), volatile memory components (e.g., DRAM, SRAM), or non-volatile memory components (e.g., flash memory, solid state drives, chalcogenide-based phase-change non-volatile memories). Computer-readable storage media can be contained in computer-readable storage devices such as solid-state drives, USB flash drives, and memory modules. Alternatively, the computer-executable instructions may be performed by specific hardware components that contain hardwired logic for performing all or a portion of disclosed methods, or by any combination of computer-readable storage media and hardware components.

The computer-executable instructions can be part of, for example, a dedicated software application or a software application that is accessed via a web browser or other software application (such as a remote computing application). Such software can be read and executed by, for example, a single computing device or in a network environment using one or more networked computers. Further, it is to be understood that the disclosed technology is not limited to any specific computer language or program. For instance, the disclosed technologies can be implemented by software written in C++, Java, Perl, JavaScript, Adobe Flash, or any other suitable programming language. Likewise, the disclosed technologies are not limited to any particular computer or type of hardware.

Furthermore, any of the software-based embodiments (comprising, for example, computer-executable instructions for causing a computer to perform any of the disclosed methods) can be uploaded, downloaded or remotely accessed in a variety of manners. For example, such instructions can be uploaded, downloaded or remotely accessed using the Internet, the World Wide Web, an intranet, cable (including fiber optic cable), magnetic communications, electromagnetic communications (including RF, microwave, and infrared communications), and electronic communications.

As used in this application and in the claims, a list of items joined by the term “and/or” can mean any combination of the listed items. For example, the phrase “A, B and/or C” can mean A; B; C; A and B; A and C; B and C; or A, B and C. As used in this application and in the claims, a list of items joined by the term “at least one of” can mean any combination of the listed terms. For example, the phrase “at least one of A, B or C” can mean A; B; C; A and B; A and C; B and C; or A, B, and C.

The disclosed methods, apparatuses and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 includes a micro-light emitting diode (LED) pixel element comprising: a mask layer and a N-type core partially in an opening of the mask layer; a quantum well structure on the N-type core including at least one quantum well, each quantum well including an active layer, and at least two barrier layers including a first barrier layer and a second barrier layer, wherein: the active layer includes at least one of AlInN, InGaN, InGaNY or InGaNSc; and the at least two barrier layers include: GaScN, wherein the active layer is in contact with and between the first barrier layer and the second barrier layer; or a GaN-based material, wherein the first barrier layer includes GaN, and is in contact with a surface of the active layer facing away from the N-type core, and the second barrier layer includes at least one of AlGaN or ScGaN, and is in contact with a surface of the first barrier layer facing away from the N-type core; and a P-cladding layer on the quantum well structure.

Example 2 includes the subject matter of Example 1, and optionally, wherein the GaScN includes Ga_{0.5}Sc_{0.5} N.

Example 3 includes the subject matter of any one of Examples 1-2, and optionally, wherein the mask layer includes Si₃N₄, the N-type core includes n-doped GaN, the active layer includes InGaN, and the P-cladding include p-doped GaN.

Example 4 includes the subject matter of any one of Examples 1-3, wherein second barrier layer AlGaN includes an Al_{z}Ga_{1-z}N layer, and wherein z≈0.3-0.4.

Example 5 includes the subject matter of any one of Examples 1-4, wherein the quantum well structure includes at least one barrier layer between the N-type core and the active layer.

Example 6 includes the subject matter of any one of Examples 1-5, wherein the AlGaN or ScGaN of the second barrier layer has, respectively, a crystalline aluminum, yttrium or scandium atomic concentration of about 30% to about 50%.

Example 7 includes the subject matter of any one of Examples 1-6, wherein: the first barrier layer has a thickness of about 5 nm to about 15 nm; the active layer has a thickness of between about 2 nm to about 5 nm; when the at least two barrier layers include GaScN, the second barrier layer has a thickness of about 5 nm to about 15 nm; and when the second barrier layer includes at least one of AlGaN or ScGaN, the second barrier layer has a thickness between about 2 nm to about 10 nm.

Example 8 includes the subject matter of any one of Examples 1-7, wherein the quantum well structure is a multiple quantum well (MQW) structure and the at least one quantum well includes a plurality of quantum wells defining the MQW structure.

Example 9 includes the subject matter of any one of Examples 1-8, wherein the active layer include InGaN, and includes: a first active sublayer including InₓGa₁₋ₓN in contact with the N-type core, wherein x has a value of up to 0.05; and a second active sublayer in contact with the first active sublayer on a side of the first active sublayer away from the N-type core, the second active layer including In_{y}Ga_{1-y}N with y≈0.4-0.45.

Example 10 includes the subject matter of any one of Examples 1-9, wherein an atomic concentration of indium in the active layer is greater than or equal to about 40%.

Example 11 includes the subject matter of any one of Examples 1-10, wherein the device is one of a core-shell nanowire or coaxial device, a nanopyramid device, an axial nanowire device, or a planar device.

Example 12 includes a method of manufacturing a micro-light emitting diode (LED) pixel structure, the method comprising: providing a wafer including a nucleation layer thereon; providing a device on the nucleation layer including: growing a mask layer on the nucleation layer, the mask layer defining an opening therein; growing a N-type core on the nucleation layer; and in the opening of the mask layer; growing a quantum well structure on the N-type core, the quantum well structure including at least one quantum well, each quantum well of the at least one quantum well including an active layer, and at least two barrier layers including a first barrier layer and a second barrier layer, wherein: the active layer includes at least one of AlInN, InGaN, InGaNY or InGaNSc; and the at least two barrier layers include: GaScN, wherein the first barrier layer is in contact with a surface of the active layer facing the N-type core, and the second barrier layer is in contact with a surface of the active layer facing away from the N-type core; or a GaN-based material, wherein the first barrier layer includes GaN, and is in contact with a surface of the active layer facing away from the N-type core, and the second barrier layer is a cap layer that includes at least one of AlGaN or ScGaN, and is in contact with a surface of the first barrier layer facing away from the N-type core; and growing a P-cladding layer on the quantum well structure, the P-cladding layer including a P-type semiconductor material.

Example 13 includes the subject matter of Example 12, and optionally, further including growing a release layer on the nucleation layer, wherein growing the mask layer includes growing the mask layer on the release layer, wherein the release layer is made of a material that is ablated by way of infrared radiation applied thereto to release the device from the wafer and the nucleation layer.

Example 14 includes the subject matter of Example 13, and optionally, wherein the release layer includes TiN, and the nucleation layer includes AlN.

Example 15 includes the subject matter of Example 14, and optionally, wherein the TiN has a thickness of about 10 nm to about 30 nm.

Example 16 includes the subject matter of any one of Examples 12-15, wherein the GaScN includes Ga_{0.5}Sc_{0.5} N.

Example 17 includes the subject matter of any one of Examples 12-16, wherein the wafer includes Si(111) or sapphire, the nucleation layer includes AlN, the mask layer includes Si₃N₄, the N-type core includes n-doped GaN, the active layer includes InGaN, and the P-cladding include p-doped GaN.

Example 18 includes the subject matter of any one of Examples 12-17, wherein the second barrier layer AlGaN includes an Al_{z}Ga_{1-z}N layer, wherein z≈0.3-0.4.

Example 19 includes the subject matter of any one of Examples 12-18, wherein the quantum well structure includes at least one barrier layer between the N-type core and the active layer.

Example 20 includes the subject matter of any one of Examples 12-19, wherein the AlGaN or ScGaN of the second barrier layer has, respectively, a crystalline aluminum, yttrium or scandium atomic concentration of about 30% to about 50%, and wherein growing the quantum well structure includes growing the second barrier layer using pulsed metalorganic chemical vapor deposition (MOCVD)at temperatures below about 600 degrees Celsius.

Example 21 includes the subject matter of any one of Examples 12-20, wherein: the first barrier layer has a thickness of about 5 nm to about 15 nm; the active layer has a thickness of between about 2 nm to about 5 nm; when the at least two barrier layers include GaScN, the second barrier layer has a thickness of about 5 nm to about 15 nm; and when the second barrier layer is a cap layer that includes at least one of AlGaN or ScGaN, the second barrier layer has a thickness between about 2 nm to about 10 nm.

Example 22 includes the subject matter of any one of Examples 12-21, wherein the quantum well structure is a multiple quantum well (MQW) structure and the at least one quantum well includes a plurality of quantum wells defining the MQW structure.

Example 23 includes the subject matter of any one of Examples 12-22, wherein the active layer include InGaN, and includes: a first active layer including InₓGaₓ₋₁N in contact with the N-type core, wherein x has a value of up to 0.05; and a second active layer in contact with the first active sublayer on a side of the first active sublayer away from the N-type core, the second active layer including In_{y}Ga_{1-y}N with y≈0.4-0.45, wherein growing the quantum well structure includes growing the In_{y}Ga_{1-y}N layer using pulsed metalorganic chemical deposition (MOCVD) at temperature below about 600 degrees Celsius.

Example 24 includes the subject matter of Example 23, and optionally, wherein the pulsed MOCVD uses NH₃ or N₂H₄ as a nitrogen source.

Example 25 includes the subject matter of any one of Examples 12-24, wherein an atomic concentration of indium in the active layer is greater than or equal to about 40%.

Example 26 includes a display comprising: a display substrate comprising a backplane; and a plurality of micro-light-emitting diode (micro-LED) element coupled to the backplane of the display substrate, wherein each of the micro-LED elements includes: a mask layer and a N-type core partially in an opening of the mask layer; a quantum well structure on the N-type core including at least one quantum well, each quantum well including an active layer, and at least two barrier layers including a first barrier layer and a second barrier layer, wherein: the active layer includes at least one of AlInN, InGaN, InGaNY or InGaNSc; and the at least two barrier layers include: GaScN, wherein the active layer is in contact with and between the first barrier layer and the second barrier layer; or a GaN-based material, wherein the first barrier layer includes GaN, and is in contact with a surface of the active layer facing away from the N-type core, and the second barrier layer includes at least one of AlGaN or ScGaN, and is in contact with a surface of the first barrier layer facing away from the N-type core; and a P-cladding layer on the quantum well structure.

Example 27 includes the subject matter of Example 26, and optionally, wherein the GaScN includes Ga_{0.5}Sc_{0.5} N.

Example 28 includes the subject matter of any one of Examples 26-27, wherein the mask layer includes Si₃N₄, the N-type core includes n-doped GaN, the active layer includes InGaN, and the P-cladding include p-doped GaN.

Example 29 includes the subject matter of any one of Examples 26-28, wherein the second barrier layer AlGaN includes an Al_{z}Ga_{1-z}N layer, and wherein z≈0.3-0.4.

Example 30 includes the subject matter of any one of Examples 26-29, wherein the quantum well structure includes at least one barrier layer between the N-type core and the active layer.

Example 31 includes the subject matter of any one of Examples 26-30, wherein the AlGaN or ScGaN of the second barrier layer has, respectively, a crystalline aluminum, yttrium or scandium atomic concentration of about 30% to about 50%.

Example 32 includes the subject matter of any one of Examples 26-31, wherein: the first barrier layer has a thickness of about 5 nm to about 15 nm; the active layer has a thickness of between about 2 nm to about 5 nm; when the at least two barrier layers include GaScN, the second barrier layer has a thickness of about 5 nm to about 15 nm; and when the second barrier layer includes at least one of AlGaN or ScGaN, the second barrier layer has a thickness between about 2 nm to about 10 nm.

Example 33 includes the subject matter of any one of Examples 26-32, wherein the quantum well structure is a multiple quantum well (MQW) structure and the at least one quantum well includes a plurality of quantum wells defining the MQW structure.

Example 34 includes the subject matter of any one of Examples 26-33, wherein the active layer include InGaN, and includes: a first active sublayer including InₓGa₁₋ₓN in contact with the N-type core, wherein x has a value of up to 0.05; and a second active sublayer in contact with the first active sublayer on a side of the first active sublayer away from the N-type core, the second active layer including In_{y}Ga_{1-y}N with y≈0.4-0.45.

Example 35 includes the subject matter of any one of Examples 26-34, wherein an atomic concentration of indium in the active layer is greater than or equal to about 40%.

Example 36 includes a product comprising one or more tangible computer- readable non-transitory storage media comprising computer-executable instructions operable to, when executed by at least one computer processor, enable the at least one computer processor to implement operations comprising: providing a wafer including a nucleation layer thereon; providing a device on the nucleation layer including: growing a mask layer on the nucleation layer, the mask layer defining an opening therein; growing a N-type core on the nucleation layer; and in the opening of the mask layer; growing a quantum well structure on the N-type core, the quantum well structure including at least one quantum well, each quantum well of the at least one quantum well including an active layer, and at least two barrier layers including a first barrier layer and a second barrier layer, wherein: the active layer includes at least one of AlInN, InGaN, InGaNY or InGaNSc; and the at least two barrier layers include: GaScN, wherein the first barrier layer is in contact with a surface of the active layer facing the N-type core, and the second barrier layer is in contact with a surface of the active layer facing away from the N-type core; or a GaN-based material, wherein the first barrier layer includes GaN, and is in contact with a surface of the active layer facing away from the N-type core, and the second barrier layer is a cap layer that includes at least one of AlGaN or ScGaN, and is in contact with a surface of the first barrier layer facing away from the N-type core; and growing a P-cladding layer on the quantum well structure, the P-cladding layer including a P-type semiconductor material.

Example 37 includes the subject matter of Example 36, and optionally, the operations further including growing a release layer on the nucleation layer, wherein growing the mask layer includes growing the mask layer on the release layer, wherein the release layer is made of a material that is ablated by way of infrared radiation applied thereto to release the device from the wafer and the nucleation layer.

Example 38 includes the subject matter of Example 37, and optionally, wherein the release layer includes TiN, and the nucleation layer includes AlN.

Example 39 includes the subject matter of Example 38, and optionally, wherein the TiN has a thickness of about 10 nm to about 30 nm.

Example 40 includes the subject matter of any one of Examples 36-39, wherein the GaScN includes Ga_{0.5}Sc_{0.5} N.

Example 41 includes the subject matter of any one of Examples 36-40, wherein the wafer includes Si(111) or sapphire, the nucleation layer includes AlN, the mask layer includes Si₃N₄, the N-type core includes n-doped GaN, the active layer includes InGaN, and the P-cladding include p-doped GaN.

Example 42 includes the subject matter of any one of Examples 36-41, wherein the second barrier layer AlGaN includes an Al_{z}Ga_{1-z}N layer, wherein z≈0.3-0.4.

Example 43 includes the subject matter of any one of Examples 36-42, wherein the quantum well structure includes at least one barrier layer between the N-type core and the active layer.

Example 44 includes the subject matter of any one of Examples 36-43, wherein the AlGaN or ScGaN of the second barrier layer has, respectively, a crystalline aluminum, yttrium or scandium atomic concentration of about 30% to about 50%, and wherein growing the quantum well structure includes growing the second barrier layer using pulsed metalorganic chemical vapor deposition (MOCVD)at temperatures below about 600 degrees Celsius.

Example 45 includes the subject matter of any one of Examples 36-44, wherein: the first barrier layer has a thickness of about 5 nm to about 15 nm; the active layer has a thickness of between about 2 nm to about 5 nm; when the at least two barrier layers include GaScN, the second barrier layer has a thickness of about 5 nm to about 15 nm; and when the second barrier layer is a cap layer that includes at least one of AlGaN or ScGaN, the second barrier layer has a thickness between about 2 nm to about 10 nm.

Example 46 includes the subject matter of any one of Examples 36-45, wherein the quantum well structure is a multiple quantum well (MQW) structure and the at least one quantum well includes a plurality of quantum wells defining the MQW structure.

Example 47 includes the subject matter of any one of Examples 36-46, wherein the active layer include InGaN, and includes: a first active layer including InₓGa₁₋ₓN in contact with the N-type core, wherein x has a value of up to 0.05; and a second active layer in contact with the first active sublayer on a side of the first active sublayer away from the N-type core, the second active layer including In_{y}Ga_{1-y}N with y≈0.4-0.45, wherein growing the quantum well structure includes growing the In_{y}Ga_{1-y}N layer using pulsed metalorganic chemical deposition (MOCVD) at temperature below about 600 degrees Celsius.

Example 48 includes the subject matter of Example 47, and optionally, wherein the pulsed MOCVD uses NH₃ or N₂H₄ as a nitrogen source.

Example 49 includes the subject matter of any one of Examples 36-48, wherein an atomic concentration of indium in the active layer is greater than or equal to about 40%.

What we claim is:

1. A micro-light emitting diode (LED) pixel element comprising:
a mask layer and a N-type core partially in an opening of the mask layer;
a quantum well structure on the N-type core including at least one quantum well, each quantum well including an active layer, and at least two barrier layers including a first barrier layer and a second barrier layer, wherein:
the active layer includes at least one of AlInN, InGaN, InGaNY or InGaNSc; and
the at least two barrier layers include:
GaScN, wherein the active layer is in contact with and between the first barrier layer and the second barrier layer; or
a GaN-based material, wherein the first barrier layer includes GaN, and is in contact with a surface of the active layer facing away from the N-type core, and the second barrier layer includes at least one of AlGaN or ScGaN, and is in contact with a surface of the first barrier layer facing away from the N-type core; and
a P-cladding layer on the quantum well structure.

2. The micro-LED pixel element of claim 1, wherein the GaScN includes Ga_{0.5}Sc_{0.5} N.

3. The micro-LED pixel element of claim 1, wherein the mask layer includes Si₃N₄, the N-type core includes n-doped GaN, the active layer includes InGaN, and the P-cladding include p-doped GaN.

4. The micro-LED pixel element of claim 1, wherein second barrier layer AlGaN includes an Al_{z}Ga_{1-z}N layer, and wherein z≈0.3-0.4.

5. The micro-LED pixel element of claim 1, wherein the quantum well structure includes at least one barrier layer between the N-type core and the active layer.

6. The micro-LED pixel element of claim 1, wherein the AlGaN or ScGaN of the second barrier layer has, respectively, a crystalline aluminum, yttrium or scandium atomic concentration of about 30% to about 50%.

7. The micro-LED pixel element of claim 1, wherein:
the first barrier layer has a thickness of about 5 nm to about 15 nm;
the active layer has a thickness of between about 2 nm to about 5 nm;
when the at least two barrier layers include GaScN, the second barrier layer has a thickness of about 5 nm to about 15 nm; and
when the second barrier layer includes at least one of AlGaN or ScGaN, the second barrier layer has a thickness between about 2 nm to about 10 nm.

8. The micro-LED pixel element of claim 1, wherein the quantum well structure is a multiple quantum well (MQW) structure and the at least one quantum well includes a plurality of quantum wells defining the MQW structure.

9. The micro-LED pixel element of claim 1, wherein the active layer include InGaN, and includes:
a first active sublayer including InₓGa₁₋ₓN in contact with the N-type core, wherein x has a value of up to 0.05; and
a second active sublayer in contact with the first active sublayer on a side of the first active sublayer away from the N-type core, the second active layer including In_{y}Ga_{1-y}N with y≈0.4-0.45.

10. The micro-LED pixel element of claim 1, wherein an atomic concentration of indium in the active layer is greater than or equal to about 40%.

11. The micro-LED pixel element of claim 1, wherein the micro-LED pixel element is one of a core-shell nanowire or coaxial micro-LED pixel element, a nanopyramid micro-LED pixel element, an axial nanowire micro-LED pixel element, or a planar micro-LED pixel element.

12. A method of manufacturing a micro-light emitting diode (LED) pixel structure, the method comprising:
providing a wafer including a nucleation layer thereon;
providing a micro-LED pixel element on the nucleation layer including:
growing a mask layer on the nucleation layer, the mask layer defining an opening therein;
growing a N-type core on the nucleation layer; and in the opening of the mask layer;
growing a quantum well structure on the N-type core, the quantum well structure including at least one quantum well, each quantum well of the at least one quantum well including an active layer, and at least two barrier layers including a first barrier layer and a second barrier layer, wherein:
the active layer includes at least one of AlInN, InGaN, InGaNY or InGaNSc; and
the at least two barrier layers include:
GaScN, wherein the first barrier layer is in contact with a surface of the active layer facing the N-type core, and the second barrier layer is in contact with a surface of the active layer facing away from the N-type core; or
a GaN-based material, wherein the first barrier layer includes GaN, and is in contact with a surface of the active layer facing away from the N-type core, and the second barrier layer is a cap layer that includes at least one of AlGaN or ScGaN, and is in contact with a surface of the first barrier layer facing away from the N-type core; and
growing a P-cladding layer on the quantum well structure, the P-cladding layer including a P-type semiconductor material.

13. The method of claim 12, further including growing a release layer on the nucleation layer, wherein growing the mask layer includes growing the mask layer on the release layer, wherein the release layer is made of a material that is ablated by way of infrared radiation applied thereto to release the micro-LED pixel element from the wafer and the nucleation layer.

14. The method of claim 13, wherein the release layer includes TiN, and the nucleation layer includes AlN.

15. The method of claim 14, wherein the TiN has a thickness of about 10 nm to about 30 nm.

16. The method of claim 12, wherein the GaScN includes Ga_{0.5}Sc_{0.5} N.

17. The method of claim 12, wherein the wafer includes Si(111) or sapphire, the nucleation layer includes AlN, the mask layer includes Si₃N₄, the N-type core includes n-doped GaN, the active layer includes InGaN, and the P-cladding include p-doped GaN.

18. The method of claim 12, wherein the second barrier layer AlGaN includes an Al_{z}Ga_{1-z}N layer, wherein z≈0.3-0.4.

19. The method of claim 12, wherein the AlGaN or ScGaN of the second barrier layer has, respectively, a crystalline aluminum, yttrium or scandium atomic concentration of about 30% to about 50%, and wherein growing the quantum well structure includes growing the second barrier layer using pulsed metalorganic chemical vapor deposition (MOCVD)at temperatures below about 600 degrees Celsius.

20. The method of claim 12, wherein the quantum well structure is a multiple quantum well (MQW) structure and the at least one quantum well includes a plurality of quantum wells defining the MQW structure.

21. The method of claim 12, wherein the active layer include InGaN, and includes:
a first active layer including in contact with the N-type core, wherein x has a value of up to 0.05; and
a second active layer in contact with the first active sublayer on a side of the first active sublayer away from the N-type core, the second active layer including In_{y}Ga_{1-y}N with y≈0.4-0.45, wherein growing the quantum well structure includes growing the In_{y}Ga_{1-y}N layer using pulsed metalorganic chemical deposition (MOCVD) at temperature below about 600 degrees Celsius.

22. The method of claim 21, wherein the pulsed MOCVD uses NH₃ or N₂H₄ as a nitrogen source.

23. The method of claim 12, wherein an atomic concentration of indium in the active layer is greater than or equal to about 40%.

24. A display comprising:
a display substrate comprising a backplane; and
a plurality of micro-light-emitting diode (micro-LED) element coupled to the backplane of the display substrate, wherein each of the micro-LED elements includes:
a mask layer and a N-type core partially in an opening of the mask layer;
a quantum well structure on the N-type core including at least one quantum well, each quantum well including an active layer, and at least two barrier layers including a first barrier layer and a second barrier layer, wherein:
the active layer includes at least one of AlInN, InGaN, InGaNY or InGaNSc; and
the at least two barrier layers include:
GaScN, wherein the active layer is in contact with and between the first barrier layer and the second barrier layer; or
a GaN-based material, wherein the first barrier layer includes GaN, and is in contact with a surface of the active layer facing away from the N-type core, and the second barrier layer includes at least one of AlGaN or ScGaN, and is in contact with a surface of the first barrier layer facing away from the N-type core; and
a P-cladding layer on the quantum well structure.

25. The display of claim 24, wherein the AlGaN or ScGaN of the second barrier layer has, respectively, a crystalline aluminum or scandium atomic concentration of about 30% to about 50%.
